(19) United States
(12) Patent Application Publication
(10) Pub. No.: US 2010/0067203 A1
(43) Pub. Date: Mar. 18, 2010

(54) APPARATUS FOR CARRYING PHOTOCONDUCTIVE INTEGRATED CIRCUITS

(75) Inventors: Safieddin Safavi-Naeini, Waterloo (CA); Mohammad Neshat, Waterloo (CA); Daryoosh Saeedkia, Waterloo (CA)

Correspondence Address: BERESKIN AND PARR LLP/S.E.N.C.R.L., s.r.l., 40 KING STREET WEST, BOX 401, TORONTO, ON, M5H 3Y2, CA

(73) Assignee: T-RAY SCIENCE INC., Waterloo (CA)

(21) Appl. No.: 12/499,348

(22) Filed: Jul. 8, 2009

Related U.S. Application Data
(60) Provisional application No. 61/078,919, filed on Jul. 8, 2008.

(51) Int. Cl. H05K 7/06

(52) U.S. Cl. 361/752

(57) ABSTRACT

Apparatus for carrying a plurality of photoconductive antennas is configured to facilitate the independent application of a voltage bias to each of the photoconductive antennas. The apparatus includes a carrier device, which comprises a support member configured for supporting a substrate containing a plurality of photoconductive integrated circuits. The support member has a side edge and a central portion having a window therein shaped for exposing the plurality of photoconductive integrated circuits to an incident optical beam. At least three contact plates are positioned on the central portion of the support member adjacent the window, and are configured to be electrically connected to an electrode of one of the photoconductive integrated circuits and to an electrode of another one of the photoconductive integrated circuits. At least two pairs of input terminals are located on the support member adjacent the side edge thereof, and are spaced from each other. The device also includes conductors for electrically connecting the contact plates to the pairs of input terminals, which comprise a pair of conductors extending from each of the contact plates. The pair of conductors comprises a first conductor connected to a terminal of one of the pairs of input terminals, and a second conductor connected to a terminal of another of the pairs of input terminals.

### FIELD

The present invention relates to systems for generating and detecting terahertz radiation, and in particular, to apparatus for carrying components of terahertz systems such as photoconductive antennas.

### BACKGROUND

Many terahertz (THz) spectroscopy and imaging systems utilize photoconductive antennas for generating and detecting terahertz radiation. Photoconductive antennas typically take the form of an integrated circuit or chip comprising a substrate having photoconductive material applied thereto, and two electrodes separated by a gap. Terahertz radiation can be generated by applying a voltage bias between the electrodes and focusing one or more laser beams onto the voltage biased photoconductor layer between the gap in the electrodes. The incident laser beam is absorbed by the photoconductive material and generates free carriers (electrons and holes) by exciting the electrons from valance band into their excited states in a conduction band. Under the influence of the voltage bias, the free carriers accelerate, thus generate and radiate a THz wave.

The present invention relates to apparatus for carrying the integrated circuits containing the terahertz photoconductive antennas and for providing a voltage bias thereto, which can be conveniently deployed in terahertz spectroscopy and terahertz imaging systems.

### SUMMARY

According to one aspect of the invention, there is provided a device for carrying photoconductive integrated circuits, comprising a support member configured for supporting a substrate containing at least one photoconductive integrated circuit, the support member having a side edge and a central portion having a window therein shaped for exposing the at least one photoconductive integrated circuit to an incident optical beam; at least two contact plates positioned on the central portion of the support member adjacent the window, each of the contact plates being configured to be electrically connected to an electrode of the photoconductive integrated circuit; at least one pair of input terminals located on the support member adjacent the side edge thereof; and conductors for electrically connecting the contact plates to the at least one pair of input terminals, the conductors comprising a first conductor extending from a first of the contact plates to a first terminal of the pair of input terminals, and a second conductor extending from a second of the contact plates to a second terminal of the pair of input terminals.

According to another aspect of the invention, there is provided a carrier device for carrying a plurality of photoconductive integrated circuits, wherein the carrier device is configured to facilitate the independent application of a voltage bias to each of the photoconductive integrated circuits. The device may comprise a support member configured for supporting a substrate containing a plurality of photoconductive integrated circuits, the support member having a side edge and a central portion having a window therein shaped for exposing the plurality of photoconductive integrated circuits to an incident optical beam, at least three contact plates positioned on the central portion of the support member adjacent the window, each of the contact plates being configured to be electrically connected to an electrode of one of the photoconductive integrated circuits and to an electrode of another one of the photoconductive integrated circuits, at least two pairs of input terminals located on the support member adjacent the side edge thereof, each of the pairs of input terminals being spaced from each other, and conductors for electrically connecting the contact plates to the pairs of input terminals, the conductors comprising a pair of conductors extending from each of the contact plates, wherein the pair of conductors comprises a first conductor connected to a terminal of one of the pairs of input terminals, and a second conductor connected to a terminal of another of the pairs of input terminals.

The window may comprise a circular aperture, and the contact plates comprises arcuate shaped contact plates equally spaced around the aperture. The support member may comprise a printed circuit board having a metal pattern formed on a front side, wherein the metal pattern comprises the contact plates, the pairs of input terminals and the conductors.

In some embodiments, the at least two pairs of input terminals comprises at least three pairs of input terminals. In other embodiments, the at least three contact plates comprises at least four contact plates, and the at least two pairs of input terminals comprises at least four pairs of input terminals.

According to yet another aspect of the invention, there is provided a device for carrying photoconductive antennas, comprising a printed circuit board configured for supporting a substrate containing a plurality of photoconductive antennas, the printed circuit board having four side edges and a central portion having an aperture therein shaped for exposing the plurality of photoconductive antennas to an incident optical beam, four contact plates positioned on the central portion of the printed circuit board around the aperture, each of the contact plates being configured to be electrically connected to an electrode of one of the photoconductive antennas and to an electrode of another one of the photoconductive antennas, four pairs of input terminals located on the printed circuit board, each of the pairs of input terminals being adjacent one of the side edges thereof, and traces on the printed circuit board for connecting the contact plates to the pairs of input terminals, the traces comprising a pair of traces extending from each of the contact plates, wherein each of the pair of traces comprise a trace connected to a terminal of one of the pairs of input terminals, and a trace connected to a terminal of another of the pairs of input terminals.

According to a further aspect of the invention, there is provided apparatus for carrying photoconductive circuits, comprising a substrate containing at least two photoconductive integrated circuits, a planar support member configured for supporting the substrate, the support member having a side edge and a central portion having an aperture therein shaped for exposing the plurality of photoconductive integrated circuits to an incident optical beam, at least two contact plates positioned on the central portion of the support member adjacent the aperture, each of the contact plates being configured to be electrically connected to an electrode of one of the photoconductive integrated circuits and to an electrode of another one of the photoconductive integrated circuits, at least two pairs of input terminals located on the support member adjacent the side edge thereof, each of the pairs of input terminals being spaced from each other, and conductors for electrically connecting the contact plates to the pairs of input terminals, the conductors comprising a pair of conductors extending from each of the contact plates, wherein the pair of conductors comprise a first conductor connected to a terminal of one of the pairs of input terminals, and a second conductor connected to a terminal of another of the pairs of input terminals.

The support member may comprise a printed circuit board, and the conductors may comprise traces etched in the printed circuit board. The at least two contact plates may comprise four contact plates, and the at least two input terminals may comprise four pairs of input terminals. The substrate may contain four photoconductive integrated circuits.

In some embodiments, the carrier apparatus also comprise a mounting block configured for receiving the support member, the mounting block having a centrally located aperture therein that registers with the window of the support member, and connectors spaced around the side edges thereof that electrically connect to the pairs of input terminals of the support member, when the support member is mounted thereon. The carrier apparatus may further comprise a translation stage, comprising a vertically extending translating block configured for holding the mounting block, and a horizontally extending base having slots therein for receiving the translating block, the translating block being operable to adjust the positions of the photoconductive integrated circuits along an X axis and a Y axis relative to the incident optical beam, which facilitates the use of the photoconductive integrated circuits in terahertz spectroscopic and imaging applications.

### BRIEF DESCRIPTION OF THE DRAWINGS

The invention will now be described, by way of example only, with reference to the following drawings, in which:

FIG. 1 is a top plan view of a carrier device made in accordance with an exemplary embodiment of the present invention;

FIG. 2 is a top plan view of the subject carrier device shown with a substrate containing a plurality of photoconductive antennas attached to the back side thereof;

FIG. 3 is a bottom plan view of the subject carrier device shown with the substrate attached thereto;

FIG. 4 is an enlarged view of the circular window of the subject carrier device shown carrying a substrate having four different types of photoconductive antennas;

FIG. 5 is a perspective back view of the subject carrier device carrying a substrate, shown mounted on an X-Y translation stage;

FIG. 6 is a perspective front view of the subject carrier device carrying a substrate, shown mounted on the X-Y translation stage;

FIG. 7 is a is a top plan view of a carrier device made in accordance with another exemplary embodiment of the present invention; and

FIG. 8 is a top plan view of a carrier device made in accordance with yet another exemplary embodiment of the present invention.

### DETAILED DESCRIPTION

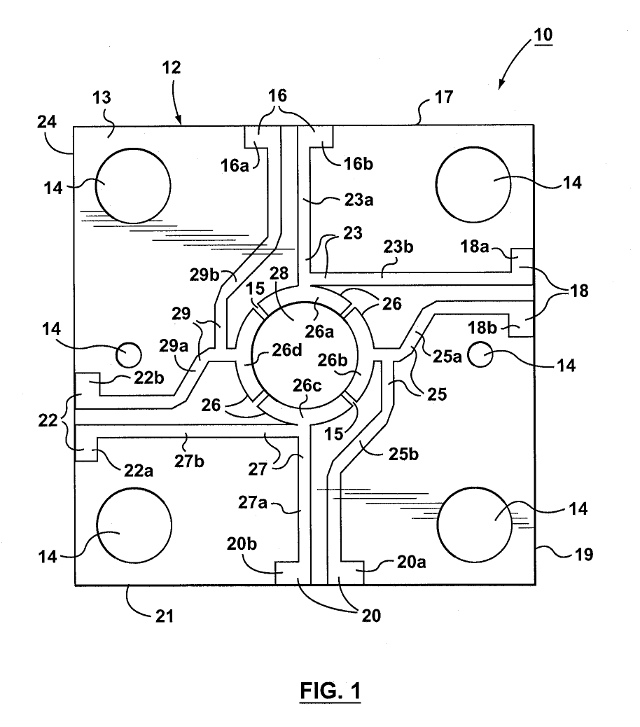

Referring to FIGS. 1-6, illustrated therein is apparatus for carrying a plurality of photoconductive antennas, made in accordance with an exemplary embodiment of the present invention. The apparatus includes a carrier device 10 for carrying a plurality of photoconductive integrated circuits, a substrate 30 containing at least two photoconductive integrated circuits, a mounting block 35 for receiving the carrier device, and a translation stage 40 for holding the mounting block 35.

Referring now to FIG. 1, in an exemplary embodiment, the carrier device 10 comprises a support member 12 configured for supporting the substrate 30, having a side edge and a central portion having a window 28 for exposing the plurality of photoconductive integrated circuits to an incident optical beam. The carrier device 10 also comprises four contact plates 26 positioned on the central portion of the support member adjacent the window 28, four pairs of input terminals 16, 18, 20, 22 located on the support member 12 adjacent the side edge thereof, and conductors 23, 25, 27, 29 that connect each of the contact plates 26 to two of the pairs of input terminals 16, 18, 20, 22, in a manner hereinafter described.

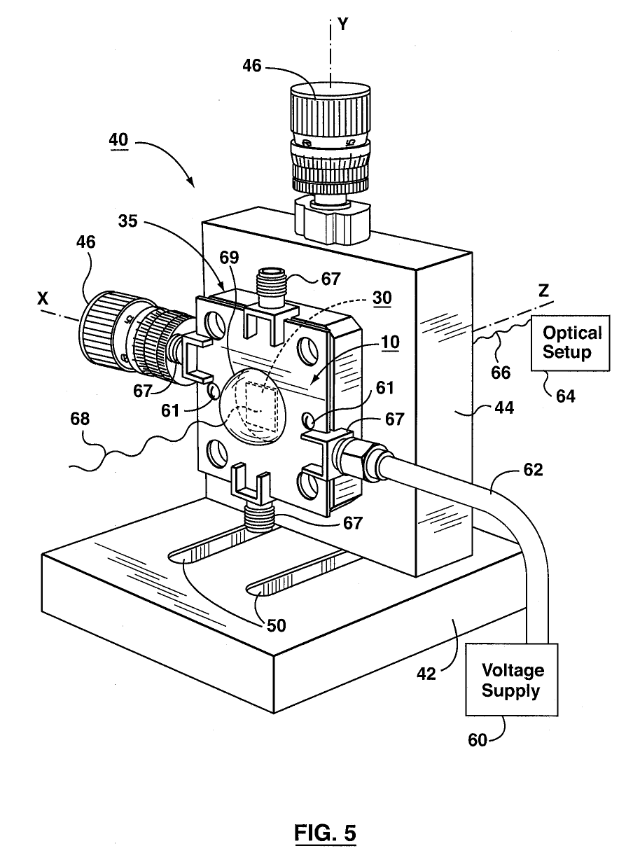

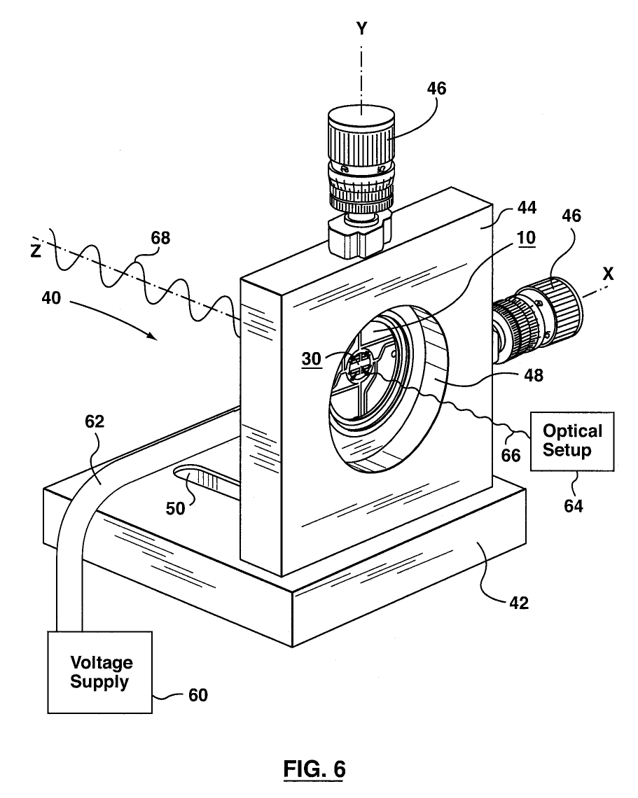

In the embodiment shown in FIG. 1, the support member 12 comprises a flat, planar, printed circuit board having four side sides, a front side 13 having a metal pattern formed therein, and several mounting apertures 14 for fastening the support member 12 to a mounting device such as the translation stage 40 (see FIGS. 5 and 6). The metal pattern may comprise the contact plates 26, the pairs of input terminals 16, 18, 20, 22 located on the side edges of the support member 12, and the conductors 23, 25, 27, 29. The printed circuit board may be made from any suitable PCB laminate such as FR4, which is economical and commercially available. The metal pattern may be produced using any known suitable methods such as etching. The conductors 23, 25, 27, 29 may comprise traces etched in the printed circuit board.

In some embodiments of the invention, including the embodiment depicted in FIG. 1, the window 28 comprises a circular aperture, and the contact plates 26 comprises four arcuate shaped contact plates regularly spaced around the window 28, and separated from each other by a gap 15. Each of the contact plates 26 is configured to be connected to the electrodes of photoconductive integrated circuits such as a terahertz photoconductive antennas, as described in more detail hereinafter. It should be appreciated, however, that the subject carrier device 10 could be configured to carry a fewer or greater number of terahertz photoconductive antennas, by configuring the carrier device to include a fewer or greater number of contact plates and pairs of input terminals connected to the corresponding contact plates. It should also be appreciated that the shape of the support member, including the number and shapes of edges or sides and the number of mounting holes, could be modified depending on design requirements.

The conductors 23, 25, 27, 29 are preferably configured to connect the pairs of input terminals 16, 18, 20, 22 to the contact plates 26 in such a way that a voltage bias applied to one of the pairs of input terminals 16, 18, 20, 22 appears only across adjacent contact plates 26. This configuration allows for the independent application of a voltage bias to each of the terahertz photoconductive antennas carried on the carrier device 10. In other words, applying a voltage bias to one of the pairs of input terminals 16, 18, 20, 22 results in a voltage bias being applied to only one of the photoconductive antennas.

The contact plates 26 preferably comprise a first contact plate 26a, a second contact plate 26b, a third contact plate 26c, and a fourth contact plate 26d. The conductor 23 preferably comprises a first pair of traces 23a, 23b extending from the first contact plate 26a, the conductor 25 preferably comprises a second pair of traces 25a, 25b extending from the second contact plate 26b, the conductor 27 preferably comprises a third pair of traces 27a, 27b extending from the third contact plate 26c, and the conductor 29 preferably comprises a fourth pair of traces 29a, 29b extending from the fourth contact plate 26d.

The pairs of input terminals 16, 18, 20 and 22 preferably comprise first input terminals 16a, 16b located on side edge 17, second input terminals 18a, 18b located on side edge 19, third input terminals 20a, 20b located on side edge 21, and fourth input terminals 22a, 22b located on side edge 24. The pairs of traces preferably comprise a first trace 23a connecting the first contact plate 26a to the first input terminal 16b, a second trace 23b connecting the first contact plate 26a to the second input terminal 18a, a third trace 25a connecting the second contact plate 26b to the second input terminal 18b, a fourth trace 25b connecting second contact plate 26b to the third input terminal 20a, a fifth trace 27a connecting the third contact plate 26c to the third input terminal 20b, a sixth trace 27b connecting the third contact plate 26c to the fourth input terminal 22a, a seventh trace 29a connecting the fourth contact plate 26d to the fourth input terminal 22b, and an eighth trace 29b connecting the fourth contact plate 26d to the first input terminal 16a.

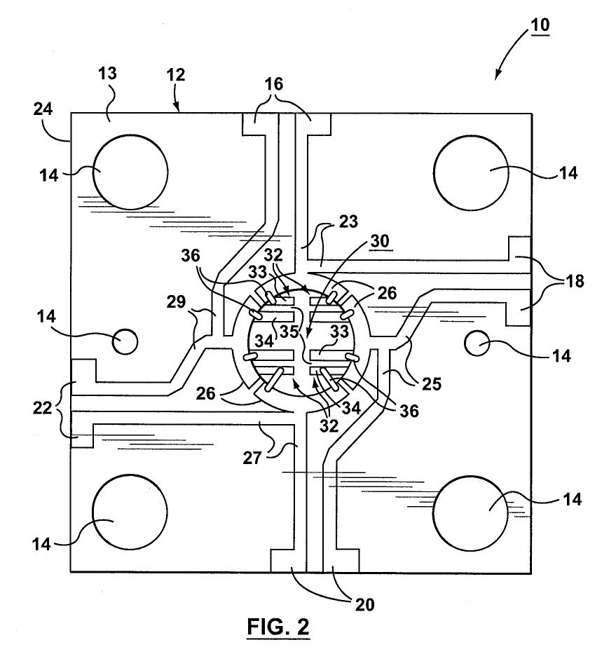

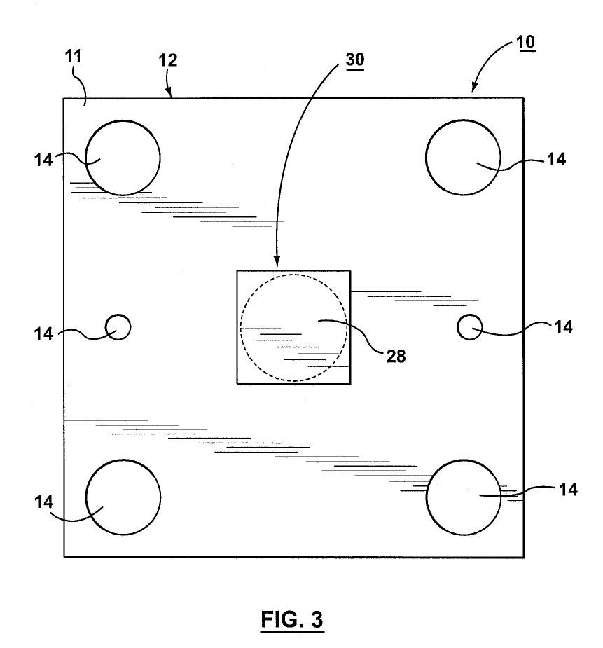

Referring now to FIGS. 2 and 3, the carrier device 10 is shown carrying a substrate 30 containing a plurality of printed circuits comprising terahertz photoconductive antennas 32. The substrate 30 is attached to the back side 11 of the carrier device 10 so that the terahertz photoconductive antennas 32 can be seen through the window 28. The substrate 30 may be attached by any known suitable means such as by use of adhesive and epoxy. It should be appreciated, however, that the terahertz photoconductive antennas 32 need not be formed on the same substrate, and that each the photoconductive antennas could be individually formed on a separate wafer or other substrate, and that each of the substrates could be attached to the carrier device in a manner similar to that described above.

The terahertz photoconductive antennas 32 are arranged on the substrate 30 such that when the substrate 30 is affixed to the carrier device 10, the electrodes 33 and 34 of photoconductive antennas 32 are located in proximity to the contact plates 26 surrounding the circular window 28. Each of the contact plates 26 is configured to be electrically connected to an electrode 33 or 34 of one of the photoconductive antennas 32 and to an electrode 33 or 34 of another of the photoconductive antennas 32. The contact plates 26 may be electrically connected to the electrodes 33 or 34 of the photoconductive antennas 32 by electrical connections 36 such as the wire bonds shown in FIG. 3 or by other suitable connections such as soldering or by conductive vias.

When a terahertz photoconductive antenna 32 is used for generating and transmitting terahertz radiation, a voltage bias is placed across the electrodes 33, 34, and a laser beam is focused onto a region of the electrode gap 35 of the terahertz photoconductive antenna in order to modulate the conductance of the electrode gap region. A current corresponding to the modulated conductance and voltage bias can be generated across the electrodes 33, 34, which results in the generation of terahertz radiation. When a terahertz photoconductive antenna 32 is used for detecting a terahertz radiation, a laser beam is focused onto a region of the electrode gap 35 of the terahertz photoconductive antenna in order to modulate the conductance of the electrode gap region. The incident terahertz radiation can be received from the back of the substrate 30, which can induce a time varying voltage across the electrodes 33, 34 of the terahertz photoconductive antenna 32, resulting in a time varying current that can be analyzed and collected from the electrodes.

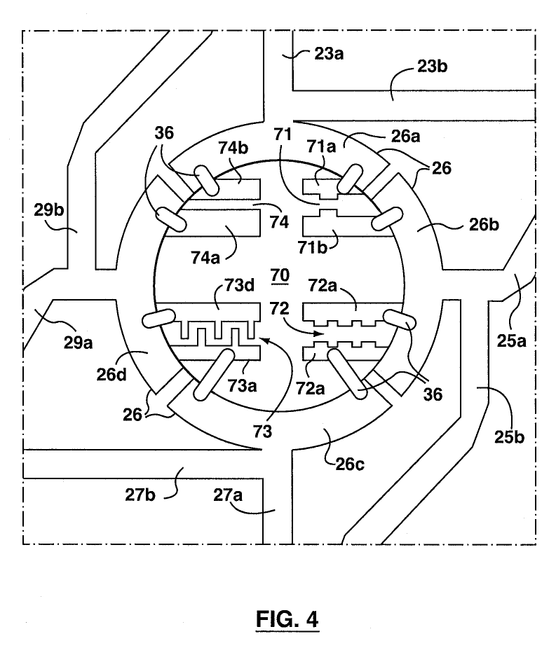

Referring now to FIG. 4, the carrier device 10 is shown carrying a substrate 70 containing four different types of terahertz photoconductive antennas 71, 72, 73 and 74, wherein the electrodes of the photoconductive antennas are exaggerated for illustrative purposes. First photoconductive antenna 71 comprises dipole electrodes 71a and 71b, second photoconductive antenna 72 comprises dipole array electrodes 72a and 72a, third photoconductive antenna 73 comprises interdigitated electrodes 73d and 73b, and fourth photoconductive antenna 74 comprises wide aperture electrodes 74a and 74b. It should be appreciated however, that carrier device 10 could be used to carry various other types of photoconductive antennas or combinations thereof. For example, the carrier device 10 could carry wafers or other substrates containing one or more photoconductive antennas having electrode patterns that are optimized for a continuous wave (CW) laser pump beam, and one or more other photoconductive antennas having electrode patterns that are optimized for a pulsed wave laser pump beam.

As shown in FIG. 4, the first contact plate 26a is electrically connected to the electrode 71a of the first photoconductive antenna 71 and to the electrode 74b of the fourth photoconductive antenna 74, the second contact plate 26b is electrically connected to the electrode 71b of the first photoconductive antenna 71 and to the electrode 72a of the second photoconductive antenna 72, the third contact plate 26c is electrically connected to the electrode 72b of the second photoconductive antenna 72 and to the electrode 73a of the third photoconductive antenna 73, and the fourth contact plate 26d is electrically connected to the electrode 73b of the third photoconductive antenna 73 and to the electrode 74a of the fourth photoconductive antenna 74.

Referring now to FIGS. 5 and 6, in some embodiments, the apparatus of the present invention may comprise a mounting block 35 for mounting thereon the carrier device 10 with the substrate 30 attached thereto, and an X-Y translation stage 40 for holding the mounting block 35 and carrier device 10, for use in a terahertz system.

The mounting block 35 is configured for receiving the carrier device 10 with substrate 30 attached thereto, and includes a centrally located aperture that registers with window 28 of support member 12, so as to expose the support member 12 to optical excitation provided by optical setup 64. Mounting block 35 includes connectors 67, which are spaced about the side edges thereof so as to register with and electrically connect to the pairs of input terminals 16, 18, 20 and 22 of the support member 12 when the carrier device 10 is mounted onto the mounting block 35.

The translation stage 40 comprises a vertically extending translating block 44, which is adjustably mounted on a horizontally extending base 42. The translating block 44 includes adjustment knobs 46 for manually adjusting the position of the carrier device 10 along the X-axis and the Y-axis, and the base 42 has slots 50 which allow the translating block 44 to be moved along the Z-axis. The translating block 44 has an aperture 48 therein, which registers with the apertures in the mounting block 35 and the support member 12, so as to allow the optical excitation 66 provided by the optical setup 64 to impinge onto the electrode gap on the substrate 30 attached to the back of the carrier device 10.

Alternatively, the X-Y translation stage could be a motorized translation stage, having a computer controller connected thereto for adjusting the positions of the carrier device 10 and the terahertz photoconductive antennas carried thereon, for facilitating experiments and for optimizing terahertz spectroscopic and imaging applications. The computer controller may accept input from the operator or execute pre-programmed instructions inputted by the operator. The block 44 can also be a motorized translation stage to move the device in Z direction.

As shown in FIG. 5, the mounting block 35 with carrier device 10 is attached to the back of the translating block 44 by two screws 61 through two of the six mounting holes 14. Carrier device 10 can facilitate the provision of a voltage bias to the electrodes of the selected photoconductive antennas from the voltage supply 60 that is connected to the carrier device by the cables 62 and the connectors 67. By adjusting the position of the carrier device 10 using adjusting means such as the adjustment knobs 46, the operator can ensure the precise application of the optical excitation 66 to the appropriate gap regions of the selected terahertz photoconductive antenna with little modification of the optical setup 64, while providing a voltage bias to the electrodes of the selected terahertz photoconductive antenna by connecting the voltage supply 60 to the appropriate connector 67. Terahertz radiation 68 can be generated and transmitted through the back of the substrate 30. A hyper-hemispheric silicon lens 69 may be mounted to the back of the substrate 30 for focusing and/or collimating the terahertz radiation 68.

The voltage supply 60 can be connected manually to one of the pairs of input terminals 16, 18, 20, 22, by the operator, in order to apply a voltage bias to the electrodes of one of the corresponding terahertz photoconductive antennas on the substrate 30. Alternatively, the voltage supply could be connected to all of the the input terminals 16, 18, 20, 22, and switches could be used to individually connect the voltage supply to a selected pair of input terminals. These switches may be operated manually or by a computer controller. Other suitable methods may be used for applying a voltage bias to a pair of input terminal, such as by using multiple voltage supplies directly connected to the corresponding pairs of input terminals.

In some embodiments of the present invention, the apparatus of the present invention could be configured so that multiple selected terahertz photoconductive antennas mounted on the carrier device could be operational at the same time. For example, a first photoconductive antenna having electrodes connected to contact plates 26a and 26b could be activated at the same time as a second photoconductive antenna having electrodes connected to contact plates 26b and 26c, by applying a positive voltage to input terminal 18a, a negative voltage to input terminals 18b and 20a, and a positive voltage to terminal 20b. This may be useful in applications such as a terahertz radiation transmission and detection system where size and number of components may be a restriction. For example, a terahertz photoconductive antenna for transmission and another for detection can be activated at the same time on the same carrier device to reduce size of such systems. In this case, a voltage bias will be required by the transmitting terahertz photoconductive antenna while a time varying current reading can be obtained from the input terminal pair corresponding to the detecting terahertz photoconductive antenna.

The apparatus of the present invention advantageously reduces the cost, time and effort needed to mount and experiment with multiple different terahertz components, by allowing for the use of only one carrier device for carrying all the components, rather than an individual carrier device for each component. In addition, precision and efficiency of adjustments are ensured with the X-Y translation stage.

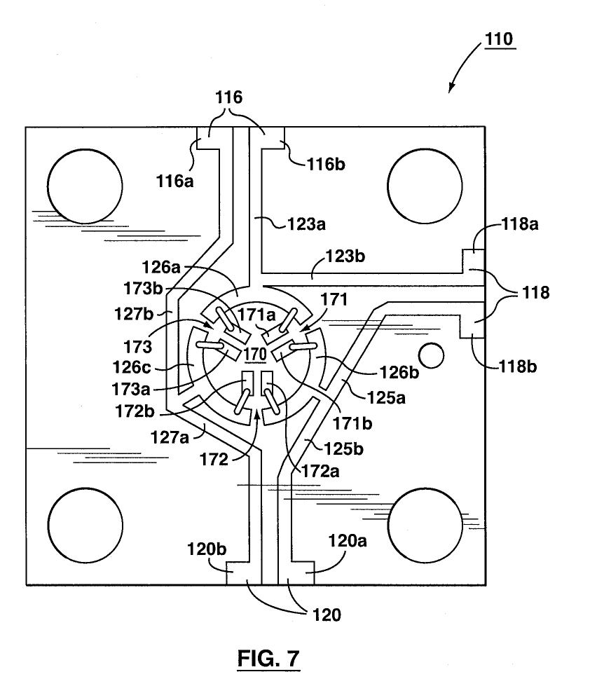

Referring now to FIG. 7, in another exemplary embodiment, the apparatus of the present invention comprise a carrier device 110, which is configured to hold a substrate 170 having at least two and preferably three photoconductive integrated circuits. Carrier device 110 comprises three contact plates 126a, 126b and 126c, and at least two and preferably three pairs of input terminals 116, 118 and 120. First contact plate 126a is connected to first terminal 116b by conductor 123a and to second input terminal 118a by conductor 123b, second contact plate 126b is connected to second input terminal 118b by conductor 125a and to third input terminal 120a by conductor 125b, and third contact plate 126c is connected to third terminal 120b by conductor 127a and to first input terminal 116a by conductor 127b.

First contact plate 126a is configured to be electrically connected to electrode 171a of first photoconductive antenna 171 and to electrode 173b of third photoconductive antenna 173, second contact plate 126b is configured to be electrically connected to electrode 171b of first photoconductive antenna 171 and electrode 172a of the second photoconductive antenna 172, and third contact plate 126c is configured to be electrically connected to the electrode 172b of the second photoconductive antenna 172 and to the electrode 173a of the third photoconductive antenna 173.

Thus when a voltage bias is applied to first pair of input terminals 116, the voltage bias appears only across the electrodes 173a, 173b of the third photoconductive antenna 173. Similarly, when a voltage bias is applied to the second pair of input terminals 118, the voltage bias appears only across the electrodes 171a, 171b of the first photoconductive antenna 171, and when a voltage bias is applied to the input terminals 120, the voltage bias appears only across the electrodes 172a, 172b of the second photoconductive antenna 172.

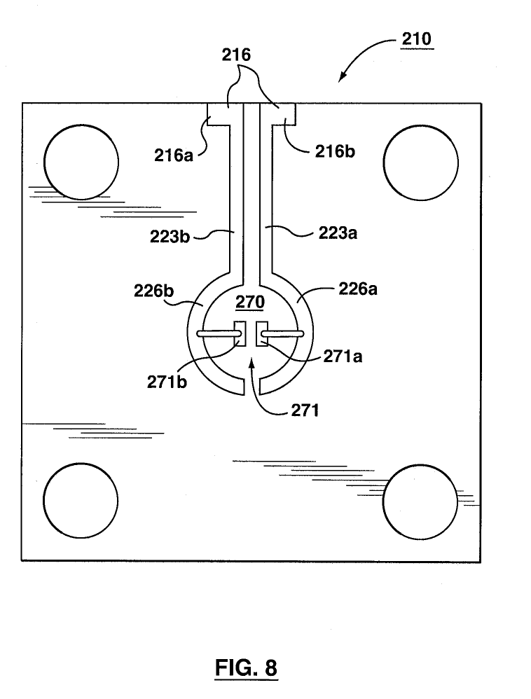

Referring to FIG. 8, in yet another exemplary embodiment, the apparatus of the present invention comprise a carrier device 210, which is configured to hold a substrate 270 having a single photoconductive integrated circuit 271. Carrier device 210 comprises first contact plate 226a and second contact plate 226b, and one pair of input terminals 216. First contact plate 226a is connected to input terminal 216b by conductor 223a and to input terminal 216a by conductor 223b. First contact plate 226a is configured to be electrically connected to electrode 271a of photoconductive antenna 271, and second contact plate 226b is electrically connected to electrode 271b of photoconductive antenna 271.

It should be noted that while the carrier devices of the present invention are particularly well adapted to carry photoconductive integrated circuits such as terahertz photoconductive antennas, the carrier devices could be used to carry other types of integrated circuits or other components of terahertz systems.

While the above description includes a number of exemplary embodiments, it should be apparent to those skilled in the art that changes and modifications can be made to these embodiments without departing from the present invention, the scope of which is defined in the appended claims.

1. A device for carrying at least one photoconductive integrated circuit, comprising:
a) a support member configured for supporting a substrate containing at least one photoconductive integrated circuit, the support member having a side edge and a central portion having a window therein shaped for exposing the at least one photoconductive integrated circuit to an incident optical beam;
b) at least two contact plates positioned on the central portion of the support member adjacent the window, each of the contact plates being configured to be electrically connected to an electrode of the photoconductive integrated circuit;
c) at least one pair of input terminals located on the support member adjacent the side edge thereof; and
d) conductors for electrically connecting the contact plates to the at least one pair of input terminals, the conductors comprising a first conductor extending from a first of the contact plates to a first terminal of the pair of input terminals, and a second conductor extending from a second of the contact plates to a second terminal of the pair of input terminals.

2. The device defined in claim 1, wherein the window comprises a circular aperture, and the contact plates comprises arcuate shaped contact plates equally spaced around the aperture.

3. The device defined claim 1, wherein the support member comprises a printed circuit board having a metal pattern formed on a front side, wherein the metal pattern comprises the contact plates, the at least one pair of input terminals and the conductors.

4. A device for carrying photoconductive integrated circuits, comprising:
a) a support member configured for supporting a substrate containing a plurality of photoconductive integrated circuits, the support member having a side edge and a central portion having a window therein shaped for exposing the plurality of photoconductive integrated circuits to an incident optical beam;
b) at least three contact plates positioned on the central portion of the support member adjacent the window, each of the contact plates being configured to be electrically connected to an electrode of one of the photoconductive integrated circuits and to an electrode of another one of the photoconductive integrated circuits;
c) at least two pairs of input terminals located on the support member adjacent the side edge thereof, each of the pairs of input terminals being spaced from each other; and
d) conductors for electrically connecting the contact plates to the pairs of input terminals, the conductors comprising a pair of conductors extending from each of the contact plates, wherein the pair of conductors comprises a first conductor connected to a terminal of one of the pairs of input terminals, and a second conductor connected to a terminal of another of the pairs of input terminals.

5. The device defined in claim 4, wherein the window comprises a circular aperture, and the contact plates comprises arcuate shaped contact plates equally spaced around the aperture.

6. The device defined in claim 4, wherein the at least two pairs of input terminals comprises three pairs of input terminals.

7. The device defined in claim 6, wherein the at least three contact plates comprises at least a first contact plate, a second contact plate and a third contact plate, and wherein the conductors comprise a first pair of traces extending from the first contact plate, a second pair of traces extending from the second contact plate, and a third pair of traces extending from the third contact plate.

8. The device defined in claim 7, wherein the at least three pairs of input terminals comprises at least a first pair of input terminals, a second pair of input terminals, and a third pair of input terminals, and wherein the first pair of traces comprises a first trace extending from the first contact plate to a terminal of the first pair of input terminals and a second trace extending from the first contact plate to a terminal of the second pair of input terminals, the second pair of traces comprises a third trace extending from the second contact plate to a terminal of the second pair of input terminals and a fourth trace extending from the second contact plate to a terminal of the third pair of input terminals, and the third pair of traces comprises a fifth trace extending from the third contact plate to a terminal of the third pair of input terminals and a sixth trace extending from the third contact plate to a terminal of the first pair of input terminals.

9. The device defined in claim 4, wherein the at least three contact plates comprises at least four contact plates, and the at least two pairs of input terminals comprises at least four pairs of input terminals.

10. A device for carrying photoconductive antennas, comprising:
a) a printed circuit board configured for supporting a wafer containing a plurality of photoconductive antennas, the printed circuit board having four side edges and a central portion having an aperture therein shaped for exposing the plurality of photoconductive antennas to an incident optical beam;
b) four contact plates positioned on the central portion of the printed circuit board around the aperture, each of the contact plates being configured to be electrically connected to an electrode of one of the photoconductive antennas and to an electrode of another one of the photoconductive antennas;
c) four pairs of input terminals located on the printed circuit board, each of the pairs of input terminals being adjacent one of the side edges thereof; and
d) traces on the printed circuit board for connecting the contact plates to the pairs of input terminals, the traces comprising a pair of traces extending from each of the contact plates, wherein each of the pair of traces comprise a trace connected to a terminal of one of the pairs of input terminals, and a trace connected to a terminal of another of the pairs of input terminals.

11. The device defined in claim 10, wherein the aperture is circular, and the contact plates comprises arcuate shaped contact plates equally spaced around the aperture.

12. The device defined in claim 10, wherein the four contact plates comprise a first contact plate, a second contact plate, a third contact plate and a fourth contact plate, and wherein the traces comprises a first pair of traces extending from the first contact plate, a second pair of traces extending from the second contact plate, a third pair of traces extending from the third contact plate, and a fourth pair of traces extending from the fourth contact plate.

13. The device defined in claim 12, wherein the first pair of traces comprises a first trace connecting the first contact plate to a terminal of a first pair of input terminals and a second trace connecting the first contact plate to a terminal of a second pair of input terminals, the second pair of traces comprises a third trace connecting the second contact plate to a terminal of the second pair of input terminals and a fourth trace connecting the second contact plate to a terminal of a third pair of input terminals, the the third pair of traces comprises a fifth trace connecting the third contact plate to a terminal of the third pair of input terminals and a sixth trace connecting the third contact plate to a terminal of a fourth pair of input terminals, and the fourth pair of traces comprises a seventh trace connecting the fourth contact plate to a terminal of the fourth pair of input terminal, and a eighth trace connecting the fourth contact plate to a terminal of the first pair of input terminals.

14. Apparatus for carrying photoconductive integrated circuits, comprising:
a) a substrate containing at least two photoconductive integrated circuits;
b) a planar support member configured for supporting the substrate, the support member having a side edge and a central portion having an aperture therein shaped for exposing the plurality of photoconductive integrated circuits to an incident optical beam;
c) at least two contact plates positioned on the central portion of the support member adjacent the aperture, each of the contact plates being configured to be electrically connected to an electrode of one of the photoconductive integrated circuits and to an electrode of another one of the photoconductive integrated circuits;
d) at least two pairs of input terminals located on the support member adjacent the side edge thereof, each of the pairs of input terminals being spaced from each other; and
e) conductors for electrically connecting the contact plates to the pairs of input terminals, the conductors comprising a pair of conductors extending from each of the contact plates, wherein the pair of conductors comprise a first conductor connected to a terminal of one of the pairs of input terminals, and a second conductor connected to a terminal of another of the pairs of input terminals.

15. The apparatus defined in claim 14, wherein the support member comprises a printed circuit board, and the conductors comprises traces etched in the printed circuit board.

16. The apparatus defined in claim 14, wherein the at least two contact plates comprise four contact plates, and the at least two pairs of input terminals comprise four pairs of input terminals.

17. The apparatus defined in claim 16, wherein the substrate contains four photoconductive integrated circuits.

18. The apparatus defined in claim 17, wherein the photoconductive printed circuits comprise photoconductive antennas.

19. The apparatus defined in claim 14, further comprising a mounting block configured for receiving the support member, the mounting block having a centrally located aperture therein that registers with the window of the support member, and connectors spaced around the side edges thereof that electrically connect to the pairs of input terminals of the support member, when the support member is mounted thereon.

20. The apparatus defined in claim 19, further comprising a translation stage, comprising a vertically extending translating block configured for holding the mounting block, and a horizontally extending base having slots therein for receiving the translating block, the translating block being operable to adjust the positions of the photoconductive integrated circuits along an X axis and a Y axis relative to the incident optical beam.
